(19) United States
(12) Patent Application Publication
(10) Pub. No.: US 2020/0203538 A1
(43) Pub. Date: Jun. 25, 2020

(54) METHOD FOR FORMING SOLAR CELL ELECTRODE AND SOLAR CELL

(71) Applicant: SAMSUNG SDI CO., LTD., Yongin-si (KR)

(72) Inventor: Ryun Min HEO, Suwon-si (KR)

(21) Appl. No.: 16/658,497

(22) Filed: Oct. 21, 2019

(30) Foreign Application Priority Data
Dec. 21, 2018 (KR) 10-2018-0167821

(51) Int. Cl. H01L 31/0224; H01L 31/0272; H01L 31/0288

(52) U.S. Cl. CPC H01L 31/022441; H01L 2031/0344; H01L 31/0288; H01L 31/02725

(57) ABSTRACT

A method for forming solar cell electrodes and a solar cell, the method including forming a first electrode layer by applying a first solar cell electrode composition, the first solar cell electrode composition including a conductive powder, a first glass frit, and an organic vehicle; forming a second electrode layer by applying a second solar cell electrode composition onto the first electrode layer, the second solar cell electrode composition including the conductive powder, a second glass frit, and the organic vehicle, the second glass frit being different from the first glass frit and containing about 15 mol % to about 30 mol % of silicon (Si) oxide; and baking the first electrode layer and the second electrode layer.

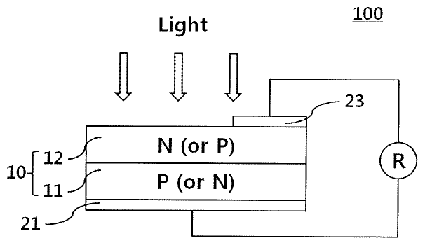

### CROSS-REFERENCE TO RELATED APPLICATION

Korean Patent Application No. 10-2018-0167821, filed on Dec. 21, 2018, in the Korean Intellectual Property Office, and entitled: “Method for Forming Solar Cell Electrode and Solar Cell,” is incorporated by reference herein in its entirety.

### BACKGROUND

### 1. Field

Embodiments relate to a method of forming solar cell electrodes and a solar cell including a solar cell electrode fabricated by the same.

### 2. Description of the Related Art

Solar cells generate electricity using the photovoltaic effect of a PN junction which converts photons of light, e.g., sunlight, into electricity. In a solar cell, front and rear electrodes may be formed on respective upper and lower surfaces of a semiconductor wafer or substrate having a PN junction. Then, the photovoltaic effect at the PN junction is induced by light entering the semiconductor wafer and electrons generated by the photovoltaic effect at the PN junction may provide electric current to the outside through the electrodes.

### SUMMARY

The embodiments may be realized by providing a method for forming a solar cell electrode, the method including forming a first electrode layer by applying a first solar cell electrode composition, the first solar cell electrode composition including a conductive powder, a first glass frit, and an organic vehicle; forming a second electrode layer by applying a second solar cell electrode composition onto the first electrode layer, the second solar cell electrode composition including the conductive powder, a second glass frit, and the organic vehicle, the second glass frit being different from the first glass frit and containing about 15 mol % to about 30 mol % of silicon (Si) oxide; and baking the first electrode layer and the second electrode layer.

The second glass frit may further include lead (Pb) oxide and tellurium (Te) oxide.

The second glass frit may further include about 10 mol % to about 15 mol % of lithium (Li) oxide.

The second glass frit may further include about 5 mol % to about 10 mol % of tungsten (W) oxide.

The first solar cell electrode composition may include about 60 wt % to about 95 wt % of the conductive powder; about 0.1 wt % to about 20 wt % of the first glass frit; and about 1 wt % to about 30 wt % of the organic vehicle, all wt % being based on a total weight of the first solar cell electrode composition.

The second solar cell electrode composition may include about 60 wt % to about 95 wt % of the conductive powder; about 0.1 wt % to about 20 wt % of the second glass frit; and about 1 wt % to about 30 wt % of the organic vehicle, all wt % being based on a total weight of the second solar cell electrode composition.

The embodiments may be realized by providing a solar cell including a substrate; a front electrode on a front surface of the substrate, the front electrode being prepared according to the method according to an embodiment; and a rear electrode on a back surface of the substrate.

The embodiments may be realized by providing a solar cell including a substrate; a front electrode including a first electrode layer on a front surface of the substrate and a second electrode layer on the first electrode layer; and a rear electrode on a back surface of the substrate, wherein the first electrode layer includes a first glass frit, the second electrode layer includes a second glass frit different from the first glass frit and containing about 15 mol % to about 30 mol % of silicon (Si) oxide, and a portion of the substrate contacting the first electrode layer has a lower sheet resistance than a portion of the substrate not contacting the first electrode layer.

The portion of the substrate contacting the first electrode layer may have a sheet resistance of about 60 Ω/□ to about 100 Ω/□, and the portion of the substrate not contacting the first electrode layer may have a sheet resistance of about 85 Ω/□ to about 160 Ω/□.

The second glass frit may further include lead (Pb) oxide and tellurium (Te) oxide.

The second glass frit may further include about 10 mol % to about 15 mol % of lithium (Li) oxide.

The second glass frit may further include about 5 mol % to about 10 mol % of tungsten (W) oxide.

### BRIEF DESCRIPTION OF THE DRAWING

Features will be apparent to those of skill in the art by describing in detail exemplary embodiments with reference to the attached drawing in which:

The FIGURE illustrates a schematic view of a solar cell according to one embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing FIGURE, the dimensions of layers and regions may be exaggerated for clarity of illustration. It will also be understood that when a layer or element is referred to as being “on” another layer or substrate, it can be directly on the other layer or element, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the singular forms, “a,” “an,” and “the” are intended to include the plural forms as well, unless the context clearly indicates otherwise. As used herein, the term “or” is not an exclusive term, e.g., “A or B” includes A, B, or A and B.

The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“X to Y”, as used herein to represent a range of a certain value, means “greater than or equal to X and less than or equal to Y” or “≥X and ≤Y”.

It will be understood that, although the terms “first”, “second”, “A”, “B”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section.

Hereinafter, a method for forming solar cell electrodes will be described in more detail.

Preparation of First Electrode Composition and Second Electrode Composition

A first solar cell electrode composition may be prepared by mixing a conductive powder with a first glass frit and an organic vehicle. A second solar cell electrode composition may be prepared by mixing the conductive powder with a second glass frit and the organic vehicle.

Conductive Powder

In an implementation, the conductive powder may include, e.g., silver (Ag) powder, gold (Au) powder, platinum (Pt) powder, palladium (Pd) powder, aluminum (Al) powder, or nickel (Ni) powder. In an implementation, the conductive powder may include, e.g., silver powder.

In an implementation, the conductive powder may have various particle shapes, e.g., a spherical particle shape, a flake particle shape, or an amorphous particle shape.

The conductive powder may have a nanometer or micrometer-scale particle size. In an implementation, the conductive powder may have an average particle diameter of dozens to several hundred nanometers, or an average particle diameter of several to dozens of micrometers. In an implementation, the conductive powder may be a mixture of two or more types of conductive powder having different particle sizes.

In an implementation, the conductive powder may have an average particle diameter (D₅₀) of, e.g., about 0.1 μm to about 10 μm (for example, about 0.1 μm, about 0.2 μm, about 0.3 μm, about 0.4 μm, about 0.5 μm, about 0.6 μm, about 0.7 μm, about 0.8 μm, about 0.9 μm, about 1 μm, about 2 μm, about 3 μm, about 4 μm, about 5 μm, about 6 μm, about 7 μm, about 8 μm, about 9 μm, or about 10 μm, for another example, about 0.5 μm to about 5 μm). Within this range, the conductive powder can provide reduction in series resistance and contact resistance. The average particle diameter (D₅₀) may be measured using a Model 1064LD particle size analyzer (CILAS Co., Ltd.) after dispersing the conductive powder in isopropyl alcohol (IPA) at 25° C. for 3 minutes via ultrasonication.

In an implementation, the conductive powder may be present in an amount of, e.g., about 60 wt % to about 95 wt % (for example, about 60 wt %, about 61 wt %, about 62 wt %, about 63 wt %, about 64 wt %, about 65 wt %, about 66 wt %, about 67 wt %, about 68 wt %, about 69 wt %, about 70 wt %, about 71 wt %, about 72 wt %, about 73 wt %, about 74 wt %, about 75 wt %, about 76 wt %, about 77 wt %, about 78 wt %, about 79 wt %, about 80 wt %, about 81 wt %, about 82 wt %, about 83 wt %, about 84 wt %, about 85 wt %, about 86 wt %, about 87 wt %, about 88 wt %, about 89 wt %, about 90 wt %, about 91 wt %, about 92 wt %, about 93 wt %, about 94 wt %, or about 95 wt %, for another example, about 70 wt % to about 90 wt %) based on the total weight of the first solar cell electrode composition or the second solar cell electrode composition. Within this range, each of the first electrode composition and the second electrode composition may help improve solar cell conversion efficiency and can be easily prepared in paste form.

First Glass Frit and Second Glass Frit

Each of the first glass flit and the second glass frit may serve to form crystal grains of the conductive powder in an emitter region by etching an anti-reflection layer and melting the conductive powder during a baking process of the corresponding electrode composition. Further, each of the first glass frit and the second glass frit may help improve adhesion of the conductive powder to a wafer and may be softened to decrease the baking temperature during the baking process.

The first solar cell electrode composition may include the first glass frit.

The first glass frit may be different from the second glass frit of the second solar cell electrode composition. In an implementation, the kind or amount of metal included in the first glass frit may be different from the kind or amount of metal included in the second glass frit. In an implementation, the first glass frit may be, e.g., free from silicon (Si) oxide. In an implementation, the first glass frit may include, e.g., less than about 15 mol (for example, about 14 mol %, about 13 mol %, about 12 mol %, about 11 mol %, about 10 mol %, about 9 mol %, about 8 mol %, about 7 mol %, about 6 mol %, about 5 mol %, about 4 mol %, about 3 mol %, about 2 mol %, about 1 mol %, or about 0 mol %). In an implementation, the first glass frit may include, e.g., more than about 30 mol % (for example, about 31 mol %, about 32 mol %, about 33 mol %, about 34 mol %, about 35 mol %, about 36 mol %, about 37 mol %, about 38 mol %, about 39 mol %, about 40 mol %, about 41 mol %, about 42 mol %, about 43 mol %, about 44 mol %, about 45 mol %, about 46 mol %, about 47 mol %, about 48 mol %, about 49 mol %, about 50 mol %, about 51 mol %, about 52 mol %, about 53 mol %, about 54 mol %, about 55 mol %, about 56 mol %, about 57 mol %, about 58 mol %, about 59 mol %, about 60 mol %, about 61 mol %, about 62 mol %, about 63 mol %, about 64 mol %, about 65 mol %, about 66 mol %, about 67 mol %, about 68 mol %, about 69 mol %, about 70 mol %, about 71 mol %, about 72 mol %, about 73 mol %, about 74 mol %, about 75 mol %, about 76 mol %, about 77 mol %, about 78 mol %, about 79 mol %, about 80 mol %, about 81 mol %, about 82 mol %, about 83 mol %, about 84 mol %, about 85 mol %, about 86 mol %, about 87 mol %, about 88 mol %, about 89 mol %, about 90 mol %, about 91 mol %, about 92 mol %, about 93 mol %, about 94 mol %, about 9 5 mol %, about 96 mol %, about 97 mol %, about 98 mol %, about 99 mol %, or about 100 mol %) of silicon (Si) oxide.

In an implementation, the first glass frit may include, e.g., lead (Pb), tellurium (Te), bismuth (Bi), lithium (Li), phosphorus (P), germanium (Ge), gallium (Ga), cerium (Ce), iron (Fe), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

In an implementation, the first glass frit may be, e.g., a lead-tellurium-oxide (Pb—Te—O) glass frit that includes elemental lead (Pb) and tellurium (Te). In an implementation, the first glass frit may further include, e.g., bismuth (Bi), lithium (Li), phosphorus (P), germanium (Ge), gallium (Ga), cerium (Ce), iron (Fe), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and aluminum (Al) (for example, lithium (Li), silicon (Si), zinc (Zn), tungsten (W), or magnesium (Mg). In an implementation, the first glass frit may include, e.g., about 20 mol % to about 50 mol % (for example, about 20 mol %, about 21 mol %, about 22 mol %, about 23 mol %, about 24 mol %, about 25 mol %, about 26 mol %, about 27 mol %, about 28 mol %, about 29 mol %, about 30 mol %, about 31 mol %, about 32 mol %, about 33 mol %, about 34 mol %, about 35 mol %, about 36 mol %, about 37 mol %, about 38 mol %, about 39 mol %, about 40 mol %, about 41 mol %, about 42 mol %, about 43 mol %, about 44 mol %, about 45 mol %, about 46 mol %, about 47 mol %, about 48 mol %, about 49 mol %, or about 50 mol %) of lead (Pb) oxide and about 30 mol % to about 60 mol % (for example, about 30 mol %, about 31 mol %, about 32 mol %, about 33 mol %, about 34 mol %, about 35 mol %, about 36 mol %, about 37 mol %, about 38 mol %, about 39 mol %, about 40 mol %, about 41 mol %, about 42 mol %, about 43 mol %, about 44 mol %, about 45 mol %, about 46 mol %, about 47 mol %, about 48 mol %, about 49 mol %, about 50 mol %, about 51 mol %, about 52 mol %, about 53 mol %, about 54 mol %, about 55 mol %, about 56 mol %, about 57 mol %, about 58 mol %, about 59 mol %, or about 60 mol %) of tellurium (Te) oxide, based on the total number of moles of components of the first glass frit. In an implementation, the first glass frit may be free of silicon (Si) oxide. In an implementation, the first glass frit may include, e.g., less than about 15 mol % of silicon (Si) oxide.

In an implementation, the first glass frit may be a lead-bismuth-tellurium-oxide (Pb—Bi—Te—O) glass frit that includes elemental lead (Pb), bismuth (Bi), and tellurium (Te). In an implementation, the first glass fit may further include, e.g., lithium (Li), phosphorus (P), germanium (Ge), gallium (Ga), cerium (Ce), iron (Fe), silicon (Si), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al) (for example, lithium (Li), silicon (Si), zinc (Zn), tungsten (W), and magnesium (Mg)). In an implementation, the first glass frit may include, e.g., a total of about 20 mol % to about 50 mol % (for example, about 20 mol %, about 21 mol %, about 22 mol %, about 23 mol %, about 24 mol %, about 25 mol %, about 26 mol %, about 27 mol %, about 28 mol %, about 29 mol %, about 30 mol %, about 31 mol %, about 32 mol %, about 33 mol %, about 34 mol %, about 35 mol %, about 36 mol %, about 37 mol %, about 38 mol %, about 39 mol %, about 40 mol %, about 41 mol %, about 42 mol %, about 43 mol %, about 44 mol %, about 45 mol %, about 46 mol %, about 47 mol %, about 48 mol %, about 49 mol %, or about 50 mol %) of lead (Pb) oxide and bismuth (Bi) oxide and about 30 mol % to about 60 mol % (for example, about 30 mol %, about 31 mol %, about 32 mol %, about 33 mol %, about 34 mol %, about 35 mol %, about 36 mol %, about 37 mol %, about 38 mol %, about 39 mol %, about 40 mol %, about 41 mol %, about 42 mol %, about 43 mol %, about 44 mol %, about 45 mol %, about 46 mol %, about 47 mol %, about 48 mol %, about 49 mol %, about 50 mol %, about 51 mol %, about 52 mol %, about 53 mol %, about 54 mol %, about 55 mol %, about 56 mol %, about 57 mol %, about 58 mol %, about 59 mol %, or about 60 mol %) of tellurium (Te) oxide, based on the total number of moles of the first glass frit. In an implementation, the first glass frit may be free of silicon (Si) oxide. In an implementation, the first glass frit may include, e.g., less than about 15 mol % of silicon (Si) oxide.

In an implementation, the first glass frit may include, e.g., lithium (Li) oxide. In an implementation, the lithium (Li) oxide may be present in an amount of, e.g., about 10 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, or about 10 mol %) in the first glass frit.

In an implementation, the first glass frit may include, e.g., magnesium (Mg) oxide. In an implementation, the magnesium (Mg) oxide may be present in an amount of, e.g., about 10 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, or about 10 mol %) in the first glass frit.

In an implementation, the first glass frit may include, e.g., zinc (Zn) oxide. In an implementation, the zinc (Zn) oxide may be present in an amount of, e.g., about 10 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, or about 10 mol %) in the first glass flit.

In an implementation, the first glass frit may include, e.g., tungsten (W) oxide. In an implementation, the tungsten (W) oxide may be present in an amount of, e.g., about 10 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, or about 10 mol %) in the first glass frit.

In an implementation, the first glass frit may be present in an amount of, e.g., about 0.1 wt % to about 20 wt % (for example, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 2 wt %, about 3 wt %, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, or about 20 wt %, for another example, about 0.5 wt % to about 10 wt %), based on the total weight of the first solar cell electrode composition. Within this range, the first glass frit may help secure stability of a PN junction under various sheet resistances, minimize serial resistance, and ultimately improve solar cell conversion efficiency.

The second solar cell electrode composition may include the second glass frit that is different from the first glass frit. In an implementation, the second glass frit may include, e.g., about 15 mol % to about 30 mol % (for example, about 15 mol %, about 16 mol %, about 17 mol %, about 18 mol %, about 19 mol %, about 20 mol %, about 21 mol %, about 22 mol %, about 23 mol %, about 24 mol %, about 25 mol %, about 26 mol %, about 27 mol %, about 28 mol %, about 29 mol %, or about 30 mol %) of silicon (Si) oxide. When the content of silicon (Si) oxide in the second glass frit falls within this range, the second solar cell electrode composition may help reduce recombination loss due to over-etching during electrode baking, thereby improving open-circuit voltage and thus solar cell efficiency, while exhibiting good adhesion to a bus bar or a ribbon.

In an implementation, in addition to elemental silicon (Si), the second glass frit may further include, e.g., lead (Pb), tellurium (Te), bismuth (Bi), lithium (Li), phosphorus (P), germanium (Ge), gallium (Ga), cerium (Ce), iron (Fe), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), or aluminum (Al).

In an implementation, the second glass frit may be a lead-tellurium-silicon-oxide (Pb—Te—Si—O) glass frit that includes elemental lead (Pb) and tellurium (Te). In an implementation, the second glass frit may further include, e.g., bismuth (Bi), lithium (Li), phosphorus (P), germanium (Ge), gallium (Ga), cerium (Ce), iron (Fe), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and aluminum (Al) (for example, lithium (Li), zinc (Zn), tungsten (W), or magnesium (Mg). In an implementation, the second glass frit may include, e.g., about 5 mol % to about 25 mol % (for example, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, about 20 mol %, about 21 mol %, about 22 mol %, about 23 mol %, about 24 mol %, or about 25 mol %, for another example, about 10 mol % to about 20 mol %) of lead (Pb) oxide and about 10 mol % to about 35 mol % (for example, about 10 mol %, about 11 mol %, about 12 mol %, about 13 mol %, about 14 mol %, about 15 mol %, about 16 mol %, about 17 mol %, about 18 mol %, about 19 mol %, about 20 mol %, about 21 mol %, about 22 mol %, about 23 mol %, about 24 mol %, about 25 mol %, about 26 mol %, about 27 mol %, about 28 mol %, about 29 mol %, about 30 mol %, about 31 mol %, about 32 mol %, about 33 mol %, about 34 mol %, or about 35 mol %, for another example, about 15 mol % to about 30 mol %) of tellurium (Te) oxide, based on the total number of moles of the second glass frit.

In an implementation, the second glass frit may be a lead-bismuth-tellurium-silicon-oxide (Pb—Bi—Te—Si—O) glass frit that includes elemental lead (Pb), bismuth (Bi), and tellurium (Te). In an implementation, the second glass frit may further include, e.g., lithium (Li), phosphorus (P), germanium (Ge), gallium (Ga), cerium (Ce), iron (Fe), zinc (Zn), tungsten (W), magnesium (Mg), cesium (Cs), strontium (Sr), molybdenum (Mo), titanium (Ti), tin (Sn), indium (In), vanadium (V), barium (Ba), nickel (Ni), copper (Cu), sodium (Na), potassium (K), arsenic (As), cobalt (Co), zirconium (Zr), manganese (Mn), and aluminum (Al) (for example, lithium (Li), zinc (Zn), tungsten (W), or magnesium (Mg). In an implementation, the second glass frit may include, e.g., a total of about 5 mol % to about 25 mol % (for example, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, about 20 mol %, about 21 mol %, about 22 mol %, about 23 mol %, about 24 mol %, or about 25 mol %, for another example, about 10 mol % to about 20 mol %) of lead (Pb) oxide and bismuth (Bi) oxide and about 10 mol % to about 35 mol % (for example, about 10 mol %, about 11 mol %, about 12 mol %, about 13 mol %, about 14 mol %, about 15 mol %, about 16 mol %, about 17 mol %, about 18 mol %, about 19 mol %, about 20 mol %, about 21 mol %, about 22 mol %, about 23 mol %, about 24 mol %, about 25 mol %, about 26 mol %, about 27 mol %, about 28 mol %, about 29 mol %, about 30 mol %, about 31 mol %, about 32 mol %, about 33 mol %, about 34 mol %, or about 35 mol %, for another example, about 15 mol % to about 30 mol %) of tellurium (Te) oxide, based on the total number of moles of the second glass frit.

In an implementation, the second glass frit may include, e.g., lithium (Li) oxide. In an implementation, the lithium (Li) oxide may be present in an amount of, e.g., about 20 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, or about 20 mol %, for another example, about 10 mol % to about 15 mol %) in the second glass frit.

In an implementation, the second glass frit may include, e.g., magnesium (Mg) oxide. In an implementation, the magnesium (Mg) oxide may be present in an amount of, e.g., about 20 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, or about 20 mol %, for another example, about 10 mol % to about 15 mol %) in the second glass frit.

In an implementation, the second glass frit may include, e.g., zinc (Zn) oxide. In an implementation, the zinc (Zn) oxide may be present in an amount of, e.g., about 20 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, or about 20 mol %, for another example, about 10 mol % to about 15 mol %) in the second glass frit.

In an implementation, the second glass frit may further include, e.g., tungsten (W) oxide. In an implementation, the tungsten (W) oxide may be present in an amount of, e.g., about 20 mol % or less (for example, about 0.1 mol %, about 0.2 mol %, about 0.3 mol %, about 0.4 mol %, about 0.5 mol %, about 0.6 mol %, about 0.7 mol %, about 0.8 mol %, about 0.9 mol %, about 1 mol %, about 2 mol %, about 3 mol %, about 4 mol %, about 5 mol %, about 6 mol %, about 7 mol %, about 8 mol %, about 9 mol %, about 10 mol %, about 11 mol %, about 12 mol %, about 13 mol %, about 14 mol %, about 15 mol %, about 16 mol %, about 17 mol %, about 18 mol %, about 19 mol %, or about 20 mol %, for another example, about 5 mol % to about 10 mol %) in the second glass frit.

In an implementation, the second glass frit may be present in an amount of, e.g., about 0.1 wt % to about 20 wt % (for example, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 2 wt %, about 3 wt %, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, or about 20 wt %, for another example, about 0.5 wt % to about 10 wt %), based on the total weight of the second solar cell electrode composition. Within this range, the second solar cell electrode composition may help provide good open-circuit voltage, thereby improving solar cell efficiency while exhibiting good adhesion.

In an implementation, (e.g., particles of) each of the first glass frit and the second glass frit may have, e.g., a spherical shape or an amorphous shape, and may have an average particle diameter (D₅₀) of, e.g., about 0.1 μm to about 10 μm (for example, about 0.1 μm, about 0.2 μm, about 0.3 μm, about 0.4 μm, about 0.5 μm, about 0.6 μm, about 0.7 μm, about 0.8 μm, about 0.9 μm, about 1 μm, about 2 μm, about 3 μm, about 4 μm, about 5 μm, about 6 μm, about 7 μm, about 8 μm, about 9 μm, or about 10 μm). The average particle diameter (D₅₀) may be measured using a Model 1064LD particle size analyzer (CILAS Co., Ltd.) after dispersing the first glass frit or the second glass frit in isopropyl alcohol (IPA) at 25° C. for 3 minutes via ultrasonication.

Each of the first glass frit and the second glass frit may be prepared from the aforementioned metals and/or oxides thereof by a suitable method. For example, each of the first glass frit and the second glass frit may be prepared by mixing the aforementioned metals and/or oxides thereof using a ball mill or a planetary mill, melting the mixture at about 800° C. to about 1,300° C., and quenching the melted mixture to 25° C., followed by pulverizing the obtained product using a disk mill, a planetary mill, or the like.

Organic Vehicle

The organic vehicle may impart suitable viscosity and rheological characteristics for printing to each of the first electrode composition and the second electrode composition through mechanical mixing with inorganic components of the composition.

The organic vehicle may be a suitable organic vehicle used in compositions for solar cell electrodes and may include, e.g., a binder resin, a solvent, and the like.

The binder resin may be selected from acrylate resins or cellulose resins. In an implementation, ethyl cellulose may be used as the binder resin. In an implementation, the binder resin may include, e.g., ethyl hydroxyethyl cellulose, nitrocellulose, blends of ethyl cellulose and phenol resins, alkyd resins, phenol resins, acrylate ester resins, xylene resins, polybutene resins, polyester resins, urea resins, melamine resins, vinyl acetate resins, wood rosin, or polymethacrylates of alcohols.

In an implementation, the solvent may include, e.g., hexane, toluene, ethyl cellosolve, cyclohexanone, butyl cellosolve, butyl carbitol (diethylene glycol monobutyl ether), dibutyl carbitol (diethylene glycol dibutyl ether), butyl carbitol acetate (diethylene glycol monobutyl ether acetate), propylene glycol monomethyl ether, hexylene glycol, terpineol, methylethylketone, benzylalcohol, γ-butyrolactone, ethyl lactate, or 2,2,4-trimethyl-1,3-pentanediol monoisobutyrate (Texanol). These may be used alone or as a mixture thereof.

In an implementation, the organic vehicle may be present in an amount of, e.g., about 1 wt % to about 30 wt % (for example, about 1 wt %, about 2 wt %, about 3 wt %, about 4 wt %, about 5 wt %, about 6 wt %, about 7 wt %, about 8 wt %, about 9 wt %, about 10 wt %, about 11 wt %, about 12 wt %, about 13 wt %, about 14 wt %, about 15 wt %, about 16 wt %, about 17 wt %, about 18 wt %, about 19 wt %, about 20 wt %, about 21 wt %, about 22 wt %, about 23 wt %, about 24 wt %, about 25 wt %, about 26 wt %, about 27 wt %, about 28 wt %, about 29 wt %, or about 30 wt %, for another example, about 3 wt % to about 25 wt %), based on the total weight of the first solar cell electrode composition or the second solar cell electrode composition. Within this range, the organic vehicle may help provide sufficient adhesive strength and good printability to the composition.

Additive

In an implementation, the first solar cell electrode composition or the second solar cell electrode composition may further include a suitable additive to enhance flowability, processability and stability, as desired. The additive may include, e.g., a dispersant, a thixotropic agent, a plasticizer, a viscosity stabilizer, an anti-foaming agent, a pigment, a UV stabilizer, an antioxidant, a coupling agent, or the like. These may be used alone or as a mixture thereof. In an implementation, the additive may be present in an amount of, e.g., about 0.1 wt % to about 5 wt % (for example, about 0.1 wt %, about 0.2 wt %, about 0.3 wt %, about 0.4 wt %, about 0.5 wt %, about 0.6 wt %, about 0.7 wt %, about 0.8 wt %, about 0.9 wt %, about 1 wt %, about 2 wt %, about 3 wt %, about 4 wt %, or about 5 wt %) based on the total weight of the first solar cell electrode composition or the second solar cell electrode composition.

Preparation of Solar Cell Electrode

First, the first solar cell electrode composition may be applied to a surface of a substrate in a predetermined pattern, followed by drying, thereby forming a first electrode layer.

Then, the second solar cell electrode composition may be applied to the substrate with the first electrode layer formed thereon, followed by drying, thereby forming a second electrode layer.

In an implementation, the application of the first solar cell electrode composition and the second solar cell electrode composition may be performed by, e.g., screen printing, gravure offset printing, rotary screen printing, or lift-off printing.

In an implementation, the drying of the first solar cell electrode composition and the second solar cell electrode composition may be performed, e.g., at about 200° C. to about 400° C. for about 10 to about 60 seconds.

Then, the resulting electrode pattern formed using the first solar cell electrode composition and the second solar cell electrode composition may be subjected to baking, thereby forming a solar cell electrode. In an implementation, the baking process may be performed, e.g., at a temperature of about 400° C. to about 980° C. or about 600° C. to about 950° C. for about 60 to about 210 seconds.

Solar Cell

The FIGURE illustrates a schematic view of a solar cell 100 according to one embodiment. The solar cell 100 may include, e.g., a substrate including a p-layer (or n-layer) 11 and an n-layer (or p-layer) 12, which will serve as an emitter; a rear electrode 21; and a front electrode 23.

The front electrode 23 may include a first electrode layer on the substrate 10 and a second electrode layer on the first electrode layer (e.g., there may not be a distinct interface or border between the first electrode layer and the second electrode layer in the front electrode 23, as illustrated in the FIGURE). In an implementation, the first electrode layer may include the first glass frit and the second electrode layer may include the second glass frit (that is different from the first glass frit and containing about 15 mol % to about 30 mol % of silicon (Si) oxide). The first glass frit and the second glass frit have been described above in detail, and repeated descriptions thereof may be omitted.

A portion of the substrate contacting the first electrode layer may have a lower sheet resistance than a portion of the substrate not contacting the first electrode. The portion of the substrate contacting the first electrode layer may help reduce series resistance due to low sheet resistance thereof and the portion of the substrate not contacting the first electrode may increase open-circuit voltage due to high sheet resistance thereof, whereby the solar cell can have good conversion efficiency. In an implementation, the portion of the substrate contacting the first electrode layer may have a sheet resistance of, e.g., about 60 Ω/□ to about 100 Ω/□ or about 70 Ω/□ to about 100 Ω/□. In an implementation, the portion of the substrate not contacting the first electrode may have a sheet resistance of, e.g., about 85 Ω/□ to about 160 Ω/□ or about 110 Ω/□ to about 160 Ω/□.

The solar cell 100 may be fabricated by performing a preliminary process for preparing the front electrode 23, in which the first solar cell electrode composition is printed on a front surface of the substrate 10, followed by drying to form the first electrode layer, and the second solar cell electrode composition is printed on the first electrode layer, followed by drying to form the second electrode layer, and performing a preliminary process for preparing the rear electrode 21, in which aluminum paste is printed on a back surface of the substrate 10 and is dried, followed by baking of the substrate.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Preparative Example 1

As a binder resin, 2 parts by weight of ethyl cellulose (STD4, Dow Chemical Company) was sufficiently dissolved in 6.5 parts by weight of terpineol (Nippon Terpine Co., Ltd.), and 90 parts by weight of spherical silver powder (AG-4-8, Dowa Hightech Co. Ltd.) having an average particle diameter of 2.0 μm and 1.5 parts by weight of glass frit A having an average particle diameter of 2.0 μm and components and amounts as shown in Table 1, were added to the binder solution, followed by mixing and kneading in a 3-roll kneader, thereby preparing a composition for solar cell electrodes.

### Preparative Examples 2 to 6

Compositions for solar cell electrodes were prepared in the same manner as in Preparative Example 1 except that glass frits B to F listed in Table 1 were used instead of glass frit A.

TABLE 1

| | Glass frit | PbO | Bi₂O₃ | TeO₂ | SiO₂ | Li₂O | MgO | ZnO | WO₃ |
|---|---|---|---|---|---|---|---|---|---|
| Preparative | Glass frit A | 14.57 | — | 24.45 | 16.95 | 11.39 | 12.80 | 12.52 | 7.32 |
| Example 1 | | | | | | | | | |
| Preparative | Glass frit B | 13.12 | 1.80 | 23.82 | 21.61 | 10.26 | 11.53 | 11.27 | 6.59 |
| Example 2 | | | | | | | | | |
| Preparative | Glass frit C | 13.36 | 1.83 | 22.41 | 22.01 | 10.45 | 11.74 | 11.48 | 6.72 |
| Example 3 | | | | | | | | | |
| Preparative | Glass frit D | 14.29 | 1.96 | 23.96 | 16.62 | 11.17 | 12.55 | 12.27 | 7.18 |
| Example 4 | | | | | | | | | |
| Preparative | Glass frit E | 25.11 | 5.80 | 38.81 | 5.87 | 6.86 | 1.87 | 6.86 | 8.82 |
| Example 5 | | | | | | | | | |
| Preparative | Glass frit F | 12.10 | — | 20.02 | 34.57 | 7.83 | 9.69 | 9.93 | 5.86 |
| Example 6 | | | | | | | | | |

*Unit: mol %

### Example 1

Aluminum paste was printed on a back surface of a wafer (a monocrystalline wafer prepared by texturing a front surface of a p-type wafer doped with boron, forming an n⁺ layer of POCl₃ on the textured surface, and forming an anti-reflection film of silicon nitride (SiNₓ:H) on the n⁺ layer), followed by drying at 300° C. Then, the composition for solar cell electrodes prepared in Preparative Example 5 was deposited over a front surface of the wafer by screen printing, followed by drying at 300° C., thereby forming the first electrode layer. Then, the composition for solar cell electrodes prepared in Preparative Example 1 was deposited over the first electrode layer by screen printing, followed by drying at 300° C., thereby forming the second electrode layer. A cell formed according to this procedure was baked in a belt-type baking furnace at 940° C. for 70 seconds, thereby fabricating a solar cell. The portion of the wafer contacting the first electrode layer had a sheet resistance of 75 Ω/□ and the portion of the wafer not contacting the first electrode layer had a sheet resistance of 115 Ω/□.

### Examples 2 to 4 and Comparative Examples 1 and 2

Solar cells were fabricated in the same manner as in Example 1 except that, instead of the composition for solar cell electrodes prepared in Preparative Example 1, the compositions as listed in Table 2 were used to form the second electrode layer.

### Evaluation Example 1: Electrical Properties

Each of the solar cells fabricated in Examples 1 to 4 and Comparative Examples 1 and 2 was evaluated as to short-circuit current (Isc, unit: A), open-circuit voltage (Voc, unit: mV), series resistance (Rs, unit: Ω), fill factor (FF, unit: %), and conversion efficiency (Eff., unit: %) using a solar cell efficiency tester (Halm, Fortix tech). Results are shown in Table 2.

### Evaluation Example 2: Adhesive Strength

Flux (952S, Kester Inc.) was applied to the second electrode layer of each of the solar cells fabricated in Examples 1 to 4 and Comparative Examples 1 and 2 and bonded to a ribbon (62Sn/36Pb/2Ag, thickness: 0.18 mm, width: 1.5 mm) at 360° C. using a soldering iron. Then, the resultant was evaluated as to adhesive strength at a peeling angle of 180° and a pulling rate of 50 mm/min using a tensioner (Model H5K-T, Tinius Olsen Co.). Results are shown in Table 2.

TABLE 2

| | Composition used to | | | | | | Adhesive |
|---|---|---|---|---|---|---|---|
| | form second electrode | | | | | | strength |
| | layer | Isc (A) | Voc (mV) | Rs (Ω) | FF (%) | Eff (%) | (N) |
| Example 1 | Composition of | 9.391 | 644.9 | 1.87 | 80.42 | 20.39 | 2.6 |
| | Preparative example 1 | | | | | | |
| Example 2 | Composition of | 9.362 | 645.1 | 1.80 | 80.60 | 20.38 | 2.7 |
| | Preparative example 2 | | | | | | |
| Example 3 | Composition of | 9.393 | 644.0 | 1.91 | 80.35 | 20.35 | 2.6 |
| | Preparative example 3 | | | | | | |
| Example 4 | Composition of | 9.378 | 643.3 | 1.85 | 80.49 | 20.33 | 3.0 |
| | Preparative example 4 | | | | | | |
| Comparative | Composition of | 9.371 | 641.8 | 1.75 | 80.60 | 20.29 | 1.1 |
| Example 1 | Preparative example 5 | | | | | | |
| Comparative | Composition of | 9.463 | 643.2 | 2.45 | 79.69 | 20.30 | 2.0 |
| Example 2 | Preparative example 6 | | | | | | |

From the results shown in Table 2, it may be seen that the solar cells of Example 1 to 4 exhibited a high open-circuit voltage and a low series resistance and good conversion efficiency while having good adhesive strength, as compared with the solar cells of Comparative Examples 1 and 2.

By way of summation and review, electrodes of such a solar cell may be formed in a predetermined pattern on a substrate by applying, patterning, and baking a composition for solar cell electrodes. In order to produce a high-efficiency solar cell, factors contributing to reduction in solar cell efficiency may be reduced. Efficiency loss of a solar cell may be broadly divided into optical loss, electron/hole recombination loss, and resistance component-induced loss.

One or more embodiments may provide a method of forming solar cell electrodes, which may help improve open-circuit voltage by reducing recombination loss due to over-etching during baking of an electrode.

One or more embodiments may provide a method of forming solar cell electrodes, which may help provide good solar cell conversion efficiency.

One or more embodiments may provide a method of forming solar cell electrodes, which may help improve adhesion of a solar cell to a bus bar or a ribbon, thereby enhancing reliability of the solar cell.

One or more embodiments may provide a method of forming solar cell electrodes, which may help improve open-circuit voltage through control over interface reaction during an electrode baking process, thereby improving solar cell conversion efficiency, while providing improved adhesive strength to a solar cell.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method for forming a solar cell electrode, the method comprising:
forming a first electrode layer by applying a first solar cell electrode composition, the first solar cell electrode composition including a conductive powder, a first glass frit, and an organic vehicle;
forming a second electrode layer by applying a second solar cell electrode composition onto the first electrode layer, the second solar cell electrode composition including the conductive powder, a second glass frit, and the organic vehicle, the second glass frit being different from the first glass frit and containing about 15 mol % to about 30 mol % of silicon (Si) oxide; and
baking the first electrode layer and the second electrode layer.

2. The method as claimed in claim 1, wherein the second glass frit further includes lead (Pb) oxide and tellurium (Te) oxide.

3. The method as claimed in claim 1, wherein the second glass frit further includes about 10 mol % to about 15 mol % of lithium (Li) oxide.

4. The method as claimed in claim 1, wherein the second glass frit further includes about 5 mol % to about 10 mol % of tungsten (W) oxide.

5. The method as claimed in claim 1, wherein the first solar cell electrode composition includes:
about 60 wt % to about 95 wt % of the conductive powder;
about 0.1 wt % to about 20 wt % of the first glass frit; and
about 1 wt % to about 30 wt % of the organic vehicle, all wt % being based on a total weight of the first solar cell electrode composition.

6. The method as claimed in claim 1, wherein the second solar cell electrode composition includes:
about 60 wt % to about 95 wt % of the conductive powder;
about 0.1 wt % to about 20 wt % of the second glass frit; and
about 1 wt % to about 30 wt % of the organic vehicle, all wt % being based on a total weight of the second solar cell electrode composition.

7. A solar cell, comprising:
a substrate;
a front electrode on a front surface of the substrate, the front electrode being prepared according to the method as claimed in claim 1; and
a rear electrode on a back surface of the substrate.

8. A solar cell, comprising:
a substrate;
a front electrode including a first electrode layer on a front surface of the substrate and a second electrode layer on the first electrode layer; and
a rear electrode on a back surface of the substrate,
wherein:
the first electrode layer includes a first glass frit,
the second electrode layer includes a second glass frit different from the first glass frit and containing about 15 mol % to about 30 mol % of silicon (Si) oxide, and
a portion of the substrate contacting the first electrode layer has a lower sheet resistance than a portion of the substrate not contacting the first electrode layer.

9. The solar cell as claimed in claim 8, wherein:
the portion of the substrate contacting the first electrode layer has a sheet resistance of about 60 Ω/□ to about 100 Ω/□, and
the portion of the substrate not contacting the first electrode layer has a sheet resistance of about 85 Ω/□ to about 160 Ω/□.

10. The solar cell as claimed in claim 8, wherein the second glass frit further includes lead (Pb) oxide and tellurium (Te) oxide.

11. The solar cell as claimed in claim 8, wherein the second glass frit further includes about 10 mol % to about 15 mol % of lithium (Li) oxide.

12. The solar cell as claimed in claim 8, wherein the second glass frit further includes about 5 mol % to about 10 mol % of tungsten (W) oxide.
